(19) United States
(12) Patent Application Publication
(10) Pub. No.: US 2023/0290911 A1
(43) Pub. Date: Sep. 14, 2023

(54) LIGHTING DEVICE HAVING HIGH COLOR-RENDERING PROPERTY AND COLOR-RENDERING PROPERTY ENHANCING METHOD THEREOF

(71) Applicant: Xiamen PVTECH Co., Ltd., Xiamen (CN)

(72) Inventors: FUXING LU, Xiamen (CN); ZHIRONG LIN, Xiamen (CN)

(73) Assignee: Xiamen PVTECH Co., Ltd., Xiamen (CN)

(21) Appl. No.: 17/847,219

(22) Filed: Jun. 23, 2022

(30) Foreign Application Priority Data
Mar. 11, 2022 (CN) 202210239329.8

(51) Int. Cl. H01L 33/50; F21K 9/64; H01L 25/075

(52) U.S. Cl. CPC H01L 33/504; F21K 9/64; H01L 25/0753; F21Y 2115/10

(57) ABSTRACT

A lighting device with high color-rendering property includes a substrate, a blue light-emitting diode (LED) die, a purple LED die and a transparent housing. The blue LED die is disposed on the substrate. The purple LED die is disposed on the substrate. The transparent housing is disposed on the substrate to form an accommodating space between the substrate and the transparent housing. The blue LED die and the purple LED die are inside the accommodating space, and the inner surface of the transparent housing is coated by a phosphor.

### BACKGROUND OF THE INVENTION

### 1. Field of the Invention

The present invention relates to a lighting device, in particular to a lighting device having high color-rendering property. The present invention further relates the color-rendering property enhancing method for lighting devices.

### 2. Description of the Prior Art

Color-rendering property is an important indicator for evaluating the lighting quality of a lighting device. The light emitted by the lighting device can more faithfully reveal the color of an object exposed under the light if the color-rendering property of the lighting device is high. A currently available white light lighting device usually includes one or more blue light-emitting diode (LED) dies and these blue LED dies are packaged in an LED chip. Then, the lights emitted by the blue LED dies stimulate the phosphor to generate a white light. However, the white light lighting device manufactured by the above method usually has poor color-rendering property, so the lighting quality thereof cannot be effectively enhanced.

### SUMMARY OF THE INVENTION

One embodiment of the present invention provides a lighting device with high color-rendering property, which includes a substrate, a blue light-emitting diode (LED) die, a purple LED die and a transparent housing. The blue LED die is disposed on the substrate. The purple LED die is disposed on the substrate. The transparent housing is disposed on the substrate to form an accommodating space between the substrate and the transparent housing. The blue LED die and the purple LED die are inside the accommodating space, and the inner surface of the transparent housing is coated by a phosphor.

In one embodiment, the phosphor is a yellow phosphor.

In one embodiment, the wavelength range of the light emitted by the purple LED die is 400 nm~420 nm.

In one embodiment, the wavelength range of the light emitted by the blue LED die is 465 nm~445 nm.

In one embodiment, the phosphor is stimulated by the light emitted by the purple LED die and the light emitted by the blue LED die to generate a white light, and the wavelength range of the white light partially overlaps the ultraviolet A (UVA) band.

Another embodiment of the present invention provides a color-rendering property enhancing method for lighting devices, which includes the following steps: providing a substrate; disposing a blue LED die on the substrate; disposing a purple LED die on the substrate; coating a phosphor on the inner surface of a transparent housing; disposing the transparent housing on the substrate to form an accommodating space for containing the blue LED die and the purple LED die; and stimulating the phosphor by the light emitted by the blue LED die and the light emitted by the purple LED die to generate a while light.

In one embodiment, the phosphor is a yellow phosphor.

In one embodiment, the wavelength range of the light emitted by the purple LED die is 400 nm~420 nm.

In one embodiment, the wavelength range of the light emitted by the blue LED die is 465 nm~445 nm.

In one embodiment, the phosphor is stimulated by the light emitted by the purple LED die and the light emitted by the blue LED die to generate a white light, and the wavelength range of the white light partially overlaps the ultraviolet A (UVA) band.

The lighting device having high color-rendering property and the color-rendering property enhancing method thereof in accordance with the embodiments of the present invention may have the following advantages:

In one embodiment of the present invention, the lighting device includes a blue LED die and a purple LED die, and the light emitted by the blue LED die and the light emitted by the purple LED die can simultaneously stimulate a phosphor to generate a white light, such that the wavelength range of the white light can overlap at least a part of the ultraviolet A (UVA) band. As a result, the color-rendering property of the lighting device can be significantly enhanced. In this way, the light emitted by the lighting device can more faithfully reveal the color of an object exposed under the light in order to effectively improve the lighting quality of the lighting device.

In one embodiment of the present invention, the lighting device includes the blue LED die and the purple LED die. The wavelength range of the light emitted by the blue LED die is 465 nm~445 nm (455 nm±10 nm) and the wavelength range of the light emitted by the purple LED die is 400 nm~420 nm (410 nm±10 nm). The above combination of the blue LED die and the purple LED die can effectively enhance the color-rendering property of the lighting device in order to effectively improve the lighting quality of the lighting device.

In one embodiment of the present invention, the lighting device includes the blue LED die and the purple LED die, and the inner surface of the transparent housing thereof is coated by a yellow phosphor. The combination of the blue LED die, the purple LED die and the yellow phosphor can greatly increase the color-rendering property of the lighting device. Thus, the lighting quality of the lighting device can be further improved.

In one embodiment of the present invention, the design of the lighting device can be applied to various types of lighting products, so this design is flexible in use and comprehensive in application.

In one embodiment of the present invention, the color-rendering property of the lighting device can be effectively enhanced by a simple structure design, so the desired technical effect can be achieved without significantly increasing the cost. Therefore, the lighting device can have a high commercial value.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a cross-sectional view of a lighting device having high color-rendering property in accordance with one embodiment of the present invention.

FIG. 2 is a cross-sectional view of a lighting device having high color-rendering property in accordance with another embodiment of the present invention.

FIG. 3 is a flow chart of a color-rendering property enhancing method for lighting devices in accordance with one embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

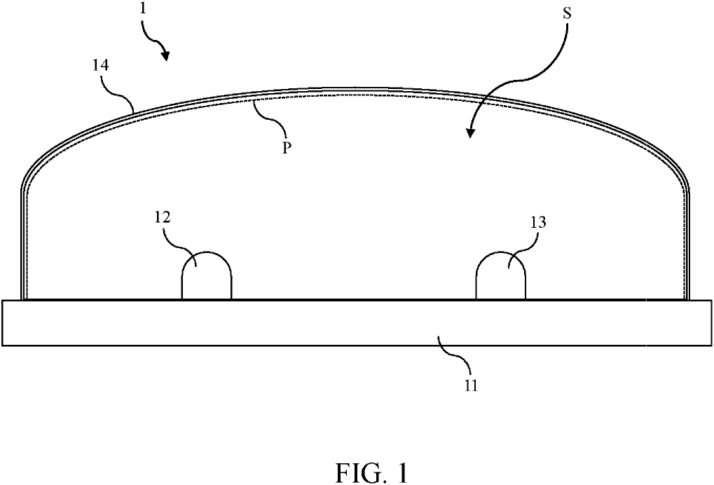

Please refer to FIG. 1, which is a cross-sectional view of a lighting device having high color-rendering property in accordance with one embodiment of the present invention. As shown in FIG. 1, the lighting device 1 includes a substrate 11, a blue light-emitting diode (LED) die 12, a purple LED die 13 and a transparent housing 14.

The blue LED die 12 is disposed on the substrate 11 and connected to a power source (not shown in the drawings). In one embodiment, the power source may be a battery, the combination of an AC power source and an AC/DC power converter or other similar devices. In one embodiment, the wavelength range of the light emitted by the blue LED die is 465 nm~445 nm (455 nm±10 nm).

The purple LED die 13 is disposed on the substrate 11 and connected to the power source (not shown in the drawings). In one embodiment, the wavelength range of the light emitted by the purple LED die is 400 nm~420 nm (410 nm±10 nm).

The transparent housing 14 is disposed on the substrate 11 to form an accommodating space S between the substrate 11 and the transparent housing 14. The blue LED die 12 and the purple LED die 13 are inside the accommodating space S. Besides, the inner surface of the transparent housing 14 is coated by a phosphor P. In one embodiment, the phosphor may be a yellow phosphor. In another embodiment, the phosphor may be other phosphors having different colors.

When the blue LED die 12 and the purple LED die 13 are driven by the power source, the light emitted by the blue LED die 12 and the light emitted by the purple LED die 13 can simultaneously stimulate the phosphor P to generate a white light. In this way, the wavelength range of the white light may overlap at least a part of the UVA band (320 nm~420 nm). In another embodiment, the wavelength range of the white light may overlap the whole UVA band. Since the wavelength range of the white light overlaps a part of the UVA band, the color-rendering property of the lighting device 1 can be greatly enhanced. Therefore, the light emitted by the lighting device 1 can more faithfully reveal the color of an object exposed under the light in order to effectively improve the lighting quality of the lighting device 1.

As set forth above, according to this embodiment, the blue LED die 12 and the purple LED die 13 are packaged in one LED chip (lighting device). Therefore, the light emitted by the blue LED die 12 and the light emitted by the purple LED die 13 can simultaneously stimulate the phosphor P coated on the inner surface of the transparent housing 14 to generate the white light. The wavelength range of the white light generated by the above mechanism can partially overlap the UVA band, so the color-rendering property of the white light emitted by the lighting device 1 can be significantly enhanced.

In addition, as previously stated, the wavelength range of the light emitted by the blue LED die may be 465 nm~445 nm (455 nm±10 nm) and the wavelength range of the light emitted by the purple LED die may be 400 nm~420 nm (410 nm±10 nm). The combination of the blue LED die 12 and the purple LED die 13 can further enhance color-rendering property of the lighting device 1 with a view to effectively improve the lighting quality of the lighting device 1.

The design of the lighting device 1 according to this embodiment can be applied to different types of lighting products, so the lighting device 1 can satisfy the requirements of different applications.

The embodiment just exemplifies the present invention and is not intended to limit the scope of the present invention; any equivalent modification and variation according to the spirit of the present invention is to be also included within the scope of the following claims and their equivalents.

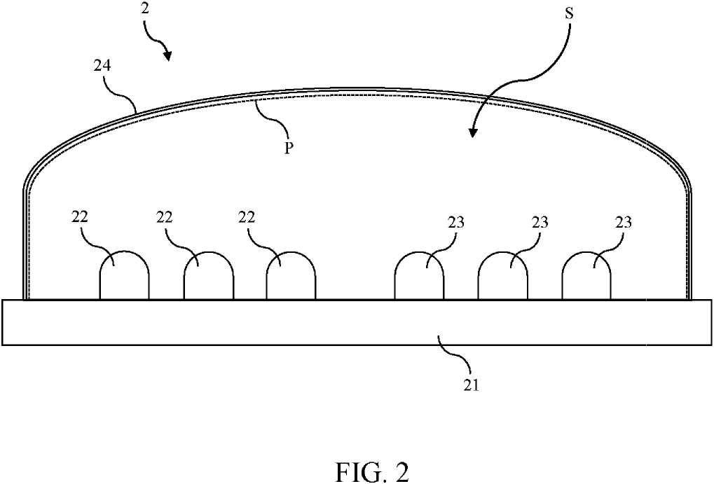

Please refer to FIG. 2, which is a cross-sectional view of a lighting device having high color-rendering property in accordance with another embodiment of the present invention. As shown in FIG. 2, the lighting device 2 includes a substrate 21, three blue light-emitting diode (LED) dies 22, three purple LED dies 23 and a transparent housing 24.

The blue LED dies 22 and the purple LED dies 23 are disposed on the substrate 11, and connected to the power source (not shown in the drawings). The transparent housing 24 is disposed on the substrate 21 to form an accommodating space S between the substrate 21 and the transparent housing 24. The blue LED dies 22 and the purple LED dies 23 are inside the accommodating space S. Similarly, the inner surface of the transparent housing 24 is coated by a phosphor P (the phosphor may be a yellow phosphor).

The difference between this embodiment and the previous embodiment is that the lighting device 2 of this embodiment has three blue LED dies 22 and three purple LED dies 23. In addition, the quantity of the blue LED dies 22 is equal to that of the purple LED dies 23. In another embodiment, the quantity of the blue LED dies 22 and the quantity of the purple LED dies 23 can be decreased or increased according to actual requirements. In still another embodiment, the quantity of the blue LED dies 22 may be different from that of the purple LED dies 23. The blue LED dies 22 and the purple LED dies 23 may be alternately arranged, such that the lights emitted by the blue LED dies 22 and the purple LED dies 23 can be uniformly mixed.

As set forth above, according to this embodiment, several blue LED dies 22 and several purple LED dies 23 are packaged in one LED chip (lighting device). Therefore, the lights emitted by the blue LED dies 22 and the lights emitted by the purple LED dies 23 can simultaneously stimulate the phosphor P coated on the inner surface of the transparent housing 24 to generate the white light. The wavelength range of the white light generated by the above mechanism can partially overlap the UVA band, so the color-rendering property of the white light emitted by the lighting device 2 can be significantly enhanced.

The design of the lighting device 2 according to this embodiment can be applied to different types of lighting products, so the lighting device 2 can satisfy the requirements of different applications.

The embodiment just exemplifies the present invention and is not intended to limit the scope of the present invention; any equivalent modification and variation according to the spirit of the present invention is to be also included within the scope of the following claims and their equivalents.

It is worthy to point out that the currently available white light lighting device usually includes one or more blue LED dies and these blue LED dies are packaged in a LED chip, and the lights emitted by these blue LED dies stimulate the phosphor to generate a white light. However, the white light lighting device manufactured by the above method usually has poor color-rendering property, so the light quality thereof cannot be effectively enhanced. On the contrary, according to one embodiment of the present invention, the lighting device includes a blue LED die and a purple LED die, and the light emitted by the blue LED die and the light emitted by the purple LED die can simultaneously stimulate a phosphor to generate a white light, such that the wavelength range of the white light can overlap at least a part of the ultraviolet A (UVA) band. As a result, the color-rendering property of the lighting device can be significantly enhanced. In this way, the light emitted by the lighting device can more faithfully reveal the color of an object exposed under the light in order to effectively improve the lighting quality of the lighting device.

Also, according to one embodiment of the present invention, the lighting device includes the blue LED die and the purple LED die. The wavelength range of the light emitted by the blue LED die is 465 nm~445 nm (455 nm±10 nm) and the wavelength range of the light emitted by the purple LED die is 400 nm~420 nm (410 nm±10 nm). The above combination of the blue LED die and the purple LED die can effectively enhance the color-rendering property of the lighting device in order to effectively improve the lighting quality of the lighting device.

Further, according to one embodiment of the present invention, the lighting device includes the blue LED die and the purple LED die, and the inner surface of the transparent housing thereof is coated by a yellow phosphor. The combination of the blue LED die, the purple LED die and the yellow phosphor can greatly increase the color-rendering property of the lighting device. Thus, the lighting quality of the lighting device can be further improved.

Moreover, according to one embodiment of the present invention, the design of the lighting device can be applied to various types of lighting products, so this design is flexible in use and comprehensive in application. As described above, the lighting device according to the embodiments of the present invention can definitely achieve great technical effects.

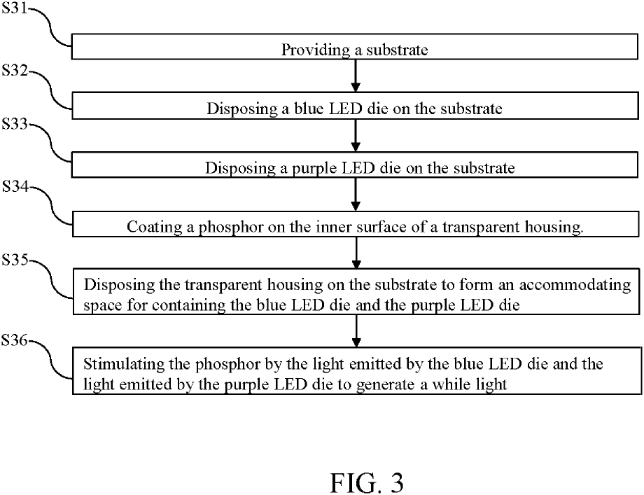

Please refer to FIG. 3, which is a flow chart of a color-rendering property enhancing method for lighting devices in accordance with one embodiment of the present invention. The color-rendering property enhancing method for lighting devices of this embodiment includes the following steps:

Step S31: providing a substrate.

Step S32: disposing a blue LED die on the substrate. As previously stated, the wavelength range of the light emitted by the blue LED die may be 465 nm~445 nm.

Step S33: disposing a purple LED die on the substrate. As previously stated, the wavelength range of the light emitted by the purple LED die may be 400 nm~420 nm.

Step S34: coating a phosphor on the inner surface of a transparent housing. As set forth above, the phosphor may be a yellow phosphor.

Step S35: disposing the transparent housing on the substrate to form an accommodating space for containing the blue LED die and the purple LED die. In this step, the blue LED die and the purple LED die are packaged in one LED chip.

Step S36: stimulating the phosphor by the light emitted by the blue LED die and the light emitted by the purple LED die to generate a while light. In this way, the wavelength range of the white light emitted by the lighting device can partially overlap the UVA band.

The embodiment just exemplifies the present invention and is not intended to limit the scope of the present invention; any equivalent modification and variation according to the spirit of the present invention is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

To sum up, according to one embodiment of the present invention, the lighting device includes a blue LED die and a purple LED die, and the light emitted by the blue LED die and the light emitted by the purple LED die can simultaneously stimulate a phosphor to generate a white light, such that the wavelength range of the white light can overlap at least a part of the ultraviolet A (UVA) band. As a result, the color-rendering property of the lighting device can be significantly enhanced. In this way, the light emitted by the lighting device can more faithfully reveal the color of an object exposed under the light in order to effectively improve the lighting quality of the lighting device.

Also, according to one embodiment of the present invention, the lighting device includes the blue LED die and the purple LED die. The wavelength range of the light emitted by the blue LED die is 465 nm~445 nm (455 nm±10 nm) and the wavelength range of the light emitted by the purple LED die is 400 nm~420 nm (410 nm±10 nm). The above combination of the blue LED die and the purple LED die can effectively enhance the color-rendering property of the lighting device in order to effectively improve the lighting quality of the lighting device.

Further, according to one embodiment of the present invention, the lighting device includes the blue LED die and the purple LED die, and the inner surface of the transparent housing thereof is coated by a yellow phosphor. The combination of the blue LED die, the purple LED die and the yellow phosphor can greatly increase the color-rendering property of the lighting device. Thus, the lighting quality of the lighting device can be further improved.

Moreover, according to one embodiment of the present invention, the design of the lighting device can be applied to various types of lighting products, so this design is flexible in use and comprehensive in application.

Furthermore, according to one embodiment of the present invention, the color-rendering property of the lighting device can be effectively enhanced by a simple structure design, so the desired technical effect can be achieved without significantly increasing the cost. Therefore, the lighting device can have a high commercial value.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A lighting device with high color-rendering property, comprising:
a substrate;
a blue light-emitting diode (LED) die, disposed on the substrate;
a purple LED die, disposed on the substrate; and
a transparent housing, disposed on the substrate to form an accommodating space between the substrate and the transparent housing;
wherein the blue LED die and the purple LED die are inside the accommodating space, and an inner surface of the transparent housing is coated by a phosphor.

2. The lighting device with high color-rendering property as claimed in claim 1, wherein the phosphor is a yellow phosphor.

3. The lighting device with high color-rendering property as claimed in claim 1, wherein a wavelength range of a light emitted by the purple LED die is 400 nm~420 nm.

4. The lighting device with high color-rendering property as claimed in claim 1, wherein a wavelength range of a light emitted by the blue LED die is 465 nm~445 nm.

5. The lighting device with high color-rendering property as claimed in claim 1, wherein the phosphor is stimulated by a light emitted by the purple LED die and a light emitted by the blue LED die to generate a white light, and a wavelength range of the white light partially overlaps an ultraviolet A (UVA) band.

6. A color-rendering property enhancing method for a lighting device, comprising:
providing a substrate;
disposing a blue LED die on the substrate;
disposing a purple LED die on the substrate;
coating a phosphor on an inner surface of a transparent housing;
disposing the transparent housing on the substrate to form an accommodating space for containing the blue LED die and the purple LED die; and
stimulating the phosphor by a light emitted by the blue LED die and a light emitted by the purple LED die to generate a while light.

7. The color-rendering property enhancing method for the lighting device as claimed in claim 6, wherein the phosphor is a yellow phosphor.

8. The color-rendering property enhancing method for the lighting device as claimed in claim 6, wherein a wavelength range of the light emitted by the purple LED die is 400 nm~420 nm.

9. The color-rendering property enhancing method for the lighting device as claimed in claim 6, wherein a wavelength range of the light emitted by the blue LED die is 465 nm~445 nm.

10. The color-rendering property enhancing method for the lighting device as claimed in claim 6, wherein a wavelength range of the white light partially overlaps an UVA band.
